(19) United States
(12) Patent Application Publication
(10) Pub. No.: US 2025/0183858 A1
(43) Pub. Date: Jun. 5, 2025

(54) AMPLIFIER WITH BYPASS MODE AND NOTCH FILTER

(71) Applicant: Skyworks Solutions, Inc., Irvine, CA (US)

(72) Inventors: Johannes Jacobus Emile Maria Hageraats, Kamuela, HI (US); Junhyung Lee, Irvine, CA (US); Rimal Deep Singh, Irvine, CA (US); Yan Yan, Irvine, CA (US); Muhammad Abduhu Ruhul Hasin, Mission Viejo, CA (US)

(21) Appl. No.: 18/963,179

(22) Filed: Nov. 27, 2024

Related U.S. Application Data
(60) Provisional application No. 63/605,449, filed on Dec. 1, 2023.

(51) Int. Cl. H03F 1/56; H03F 1/26; H03F 3/24

(52) U.S. Cl. CPC H03F 1/565; H03F 1/26; H03F 3/245; H03F 2200/294; H03F 2200/378; H03F 2200/387; H03F 2200/391; H03F 2200/451; H03F 2203/21157

(57) ABSTRACT

A low-noise radio frequency amplifier can include a pair of field-effect transistors connected to form a cascode buffer. The radio frequency amplifier can include a bypass path including a first capacitor and an inductor connected to an output of the amplifier, wherein the first capacitor and the inductor are tuned to attenuate a range of frequencies at the output of the amplifier. The radio frequency amplifier can include one or more switches to selectively connect one or more inputs of the amplifier to the bypass path. When the bypass path is in use, the first capacitor and the inductor provide impedance matching at the output of the amplifier. When the low-noise amplifier is providing amplification of radio frequency signals, the bypass path is disconnected from the output, and the first capacitor and the inductor operate as a notch filter to attenuate undesired frequencies in the signal output.

### BACKGROUND

### Field of the Invention

The present disclosure relates to front-end architectures for wireless applications.

### Description of the Related Art

In wireless applications, a signal to be transmitted is typically generated by a transceiver, amplified by a power amplifier, filtered by a filter, and routed to an antenna by a switch network. Such a signal transmitted through the antenna has a relatively high power.

In a generally reverse manner, a relatively weaker signal received through an antenna is typically routed from the antenna by a switch network, filtered by a filter, amplified by a low-noise amplifier, and provided to the transceiver.

### SUMMARY

In some aspects, the techniques described herein relate to a radio frequency amplifier including: an output, a plurality of transistors arranged to form an amplification path coupled to the output, and a bypass path coupled to the output; an LC component including a first capacitor and an inductor connected to an output of the amplifier; and a switch to selectively connect an input of the radio frequency amplifier to the bypass path during a bypass mode of operation and to disconnect the input of the radio frequency amplifier from the bypass path in a gain mode of operation, the LC component connected to the amplification path in the gain mode of operation and connected to the bypass path in the bypass mode of operation.

In some aspects, the techniques described herein relate to a radio frequency amplifier wherein the LC component provides impedance matching at the output in the bypass mode of operation.

In some aspects, the techniques described herein relate to a radio frequency amplifier wherein the bypass path is to connect the input of the amplifier to the output of the amplifier without signal amplification.

In some aspects, the techniques described herein relate to a radio frequency amplifier wherein the amplifier includes no more than a single inductor.

In some aspects, the techniques described herein relate to a radio frequency amplifier further including a second capacitor connected in parallel with the inductor.

In some aspects, the techniques described herein relate to a radio frequency amplifier wherein the LC component and the second capacitor form a notch filter tuned to attenuate a range of frequencies at the output in the gain mode of operation.

In some aspects, the techniques described herein relate to a radio frequency amplifier wherein the first capacitor or the second capacitor is a variable capacitor.

In some aspects, the techniques described herein relate to a radio frequency amplifier wherein the amplification path is a cascode buffer including two or more field-effect transistors which form an input stage and an output stage.

In some aspects, the techniques described herein relate to a radio frequency amplifier wherein each one of the plurality of inputs is connected to the bypass path by a corresponding capacitor.

In some aspects, the techniques described herein relate to a radio frequency amplifier wherein the amplifier is a low-noise amplifier.

In some aspects, the techniques described herein relate to a radio frequency front-end module including: an antenna switch module; a transmit path; and a receive path including an amplifier and a receive filter, the amplifier including an output, a plurality of transistors arranged to form an amplification path coupled to the output, a bypass path coupled to the output, an LC component including a first capacitor and an inductor connected to an output of the amplifier; and a switch to selectively connect an input of the amplifier to the bypass path during a bypass mode of operation and to disconnect the input of the amplifier from the bypass path in a gain mode of operation, the LC component connected to the amplification path in the gain mode of operation and connected to the bypass path in the bypass mode of operation.

In some aspects, the techniques described herein relate to a radio frequency front-end module wherein the amplifier is a low noise amplifier and the LC component provides impedance matching at the output in the bypass mode of operation.

In some aspects, the techniques described herein relate to a radio frequency front-end module wherein the bypass path is to connect the input of the amplifier to the output without signal amplification.

In some aspects, the techniques described herein relate to a radio frequency front-end module further including a second capacitor connected in parallel with the inductor.

In some aspects, the techniques described herein relate to a radio frequency front-end module wherein the LC component and the second capacitor form a notch filter tuned to attenuate a range of frequencies at the output of the amplifier in the gain mode of operation.

In some aspects, the techniques described herein relate to a radio frequency front-end module wherein the first capacitor or the second capacitor is a variable capacitor.

In some aspects, the techniques described herein relate to a radio frequency front-end module wherein the amplification path is a cascode buffer including two or more field-effect transistors which form an input stage and an output stage.

In some aspects, the techniques described herein relate to a radio frequency front-end module wherein each one of the plurality of inputs is connected to the bypass path by a corresponding capacitor.

In some aspects, the techniques described herein relate to a mobile device including: a transceiver; a front-end module communicatively connected to the transceiver, the front-end module including an antenna switch module, a transmit path, and a receive path including an amplifier and a receive filter, the amplifier including an output, a plurality of transistors arranged to form an amplification path coupled to the output, a bypass path coupled to the output, an LC component including a first capacitor and an inductor connected to an output of the amplifier; and a switch to selectively connect an input of the amplifier to the bypass path during a bypass mode operation and to disconnect the input of the radio frequency amplifier from the bypass path in a gain mode of operation, the LC component connected to the amplification path in the gain mode of operation and connected to the bypass path in the bypass mode of operation; and an antenna communicatively connected to the front-end module.

In some aspects, the techniques described herein relate to a radio frequency front-end system including: a transmit path configured to transmit in at least one transmit band; and a receive path configured to receive in at least one receive band, the receive path including an amplifier, the amplifier including an output, a plurality of transistors arranged to form an amplification path coupled to the output, a bypass path coupled to the output, an inductor, at least one capacitor, and a first switch; and a controller configured to control the first switch to connect an input of the amplifier to the bypass path during a bypass mode of operation and to disconnect the input of the amplifier from the bypass path in a gain mode of operation, the inductor and the at least one capacitor connected in series with one another and in parallel with an output load of the amplifier to form a band-stop filter in the gain mode, and at least one of the inductor and the at least one capacitor connected in series with the output load in the bypass mode.

In some aspects, the techniques described herein relate to a radio frequency front-end system wherein the at least one receive band includes a receive band of a frequency division duplex band and the at least one transmit band includes a transmit band of the frequency division duplex band, the band-stop filter configured to attenuate signals in transmit band of the frequency division duplex band.

In some aspects, the techniques described herein relate to a radio frequency front-end system wherein the bypass path is configured to connect the input of the amplifier to the output of the amplifier without signal amplification.

In some aspects, the techniques described herein relate to a radio frequency front-end system wherein the bypass path and the band-stop filter together include no more than a single inductor.

In some aspects, the techniques described herein relate to a radio frequency front-end system further wherein the at least one capacitor includes a variable capacitor, the controller configured to set the variable capacitor to a first capacitance in the gain mode and to set the variable capacitor to a second capacitance in the bypass mode.

In some aspects, the techniques described herein relate to a radio frequency front-end system wherein the amplifier is a low noise amplifier.

In some aspects, the techniques described herein relate to a radio frequency front-end system wherein the amplification path includes a cascode amplifier including two or more field-effect transistors which form an input stage and an output stage.

In some aspects, the techniques described herein relate to a radio frequency module including a module packaging containing the radio frequency front-end system.

In some aspects, the techniques described herein relate to a radio frequency amplifier including: an output, a plurality of transistors arranged to form an amplification path coupled to the output, and a bypass path coupled to the output; an inductor and at least one capacitor; and a switch configured to selectively connect an input of the radio frequency amplifier to the bypass path during a bypass mode of operation and to disconnect the input of the radio frequency amplifier from the bypass path in a gain mode of operation, the inductor and the at least one capacitor are connected series with one another and in parallel with an output load of the radio frequency amplifier to form a band-stop filter in the gain mode, and at least one of the inductor and the at least one capacitor connected in series with the output load of the radio frequency amplifier in the bypass mode.

In some aspects, the techniques described herein relate to a radio frequency amplifier wherein the band-stop filter configured to attenuate signals in a transmit band of a frequency division duplex band.

In some aspects, the techniques described herein relate to a radio frequency amplifier wherein the bypass path is configured to connect the input of the radio frequency amplifier to the output of the radio frequency amplifier without signal amplification.

In some aspects, the techniques described herein relate to a radio frequency amplifier wherein the bypass path and the band-stop filter together include no more than a single inductor.

In some aspects, the techniques described herein relate to a radio frequency amplifier wherein the at least one capacitor includes a variable capacitor.

In some aspects, the techniques described herein relate to a radio frequency amplifier wherein the radio frequency amplifier is a low noise amplifier in a radio frequency receive path.

In some aspects, the techniques described herein relate to a radio frequency amplifier wherein the amplification path includes a cascode amplifier including two or more field-effect transistors which form an input stage and an output stage.

In some aspects, the techniques described herein relate to a mobile device including: a transceiver; a front-end system coupled to the transceiver and including: a transmit path configured to transmit in at least one transmit band; a receive path configured to receive in at least one receive band, the receive path including an amplifier, the amplifier including an output, a plurality of transistors arranged to form an amplification path coupled to the output, a bypass path coupled to the output, an inductor, at least one capacitor, and a first switch; and a controller configured to control the first switch to connect an input of the amplifier to the bypass path during a bypass mode of operation and to disconnect the input of the amplifier from the bypass path in a gain mode of operation, the inductor and the at least one capacitor connected in series with one another and in parallel with an output load the receive path to form a band-stop filter in the gain mode, and at least one of the inductor and the at least one capacitor connected in series with the output load in the bypass mode; and an antenna communicatively connected to the front-end system.

In some aspects, the techniques described herein relate to a mobile device wherein the at least one receive band includes a receive band of a frequency division duplex band and the at least one transmit band includes a transmit band of the frequency division duplex band, the band-stop filter configured to attenuate signals in transmit band of the frequency division duplex band.

In some aspects, the techniques described herein relate to a mobile device further wherein the at least one capacitor includes a variable capacitor, the controller configured to set the variable capacitor to a first capacitance in the gain mode and to set the variable capacitor to a second capacitance in the bypass mode.

In some aspects, the techniques described herein relate to a mobile device wherein the bypass path is configured to connect the input of the amplifier to the output of the amplifier without signal amplification.

In some aspects, the techniques described herein relate to a mobile device wherein the bypass path and the band-stop filter together include no more than a single inductor.

In some aspects, the techniques described herein relate to a radio frequency amplifier including a pair of field-effect transistors connected to form a cascode buffer, a bypass path including a first capacitor and an inductor connected to an output of the amplifier, wherein the first capacitor and the inductor are tuned to attenuate a range of frequencies at the output of the amplifier, and a switch to selectively connect an input of the amplifier to the bypass path.

In some aspects, the techniques described herein relate to a radio frequency amplifier wherein the bypass path is to connect the input of the amplifier to the output of the amplifier without signal amplification.

In some aspects, the techniques described herein relate to a radio frequency amplifier wherein the bypass path includes no more than a single inductor.

In some aspects, the techniques described herein relate to a radio frequency amplifier further including a second capacitor connected in parallel with the inductor.

In some aspects, the techniques described herein relate to a radio frequency amplifier wherein the first capacitor, the second capacitor, and the inductor form a notch filter tuned to attenuate a range of frequencies at the output of the amplifier.

In some aspects, the techniques described herein relate to a radio frequency amplifier wherein the first capacitor or the second capacitor is a variable capacitor.

In some aspects, the techniques described herein relate to a radio frequency amplifier wherein the cascode buffer further includes two or more field-effect transistors associated with a plurality of inputs of the amplifier.

In some aspects, the techniques described herein relate to a radio frequency amplifier wherein each one of the plurality of inputs is connected to the bypass path by a corresponding capacitor.

In some aspects, the techniques described herein relate to a radio frequency amplifier wherein the amplifier is a low-noise amplifier.

In some aspects, the techniques described herein relate to a radio frequency front-end module including: an antenna switch module, a transmit path including a power amplifier and a transmit filter, and a receive path including a low-noise amplifier and a receive filter, wherein the low-noise amplifier is the radio frequency amplifier.

In some aspects, the techniques described herein relate to a mobile device including: a baseband system, a transceiver communicatively connected to the baseband system, a front-end module communicatively connected to the transceiver, the front-end module including an antenna switch module, a transmit path including a power amplifier and a transmit filter, and a receive path including a low-noise amplifier and a receive filter, wherein the low-noise amplifier includes a pair of field-effect transistors connected to form a cascode buffer, a bypass path including a first capacitor and an inductor connected to an output of the amplifier, and a switch to selectively connect an input of the amplifier to the bypass path, an antenna communicatively connected to the front-end module, and a power management system.

### BRIEF DESCRIPTION OF THE DRAWINGS

Throughout the drawings, reference numbers are re-used to indicate correspondence between referenced elements. The drawings are provided to illustrate embodiments of the inventive subject matter described herein and not to limit the scope thereof.

FIG. 1 is a schematic diagram of one example of a communication network.

FIG. 2A is a schematic diagram of one example of a downlink channel using multi-input and multi-output (MIMO) communications.

FIG. 2B is schematic diagram of one example of an uplink channel using MIMO communications.

FIG. 3 is a schematic diagram of one embodiment of a mobile device.

FIG. 4A is a schematic diagram of an exemplary ultrahigh band (UHB) transmit and receive module.

FIG. 4B is a schematic diagram of an exemplary high band (HB) transmit and receive module.

FIG. 4C is a schematic diagram of an exemplary uplink carrier aggregation and MIMO module.

FIGS. 5A-5C are schematic diagrams of one embodiment of a power amplifier.

FIGS. 6A-6C are schematic diagrams of another embodiment of a power amplifier.

FIGS. 7A-7C are schematic diagrams of yet another embodiment of a power amplifier.

FIGS. 8A-8C are schematic diagrams of an additional embodiment of a power amplifier.

FIG. 9A is a schematic diagram of one embodiment of a packaged module.

FIG. 9B is a schematic diagram of a cross-section of the packaged module of FIG. 9A taken along the lines 9B-9B.

### DETAILED DESCRIPTION OF CERTAIN EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

The International Telecommunication Union (ITU) is a specialized agency of the United Nations (UN) responsible for global issues concerning information and communication technologies, including the shared global use of radio spectrum.

The 3rd Generation Partnership Project (3GPP) is a collaboration between groups of telecommunications standard bodies across the world, such as the Association of Radio Industries and Businesses (ARIB), the Telecommunications Technology Committee (TTC), the China Communications Standards Association (CCSA), the Alliance for Telecommunications Industry Solutions (ATIS), the Telecommunications Technology Association (TTA), the European Telecommunications Standards Institute (ETSI), and the Telecommunications Standards Development Society, India (TSDSI).

Working within the scope of the ITU, 3GPP develops and maintains technical specifications for a variety of mobile communication technologies, including, for example, second generation (2G) technology (for instance, Global System for Mobile Communications (GSM) and Enhanced Data Rates for GSM Evolution (EDGE)), third generation (3G) technology (for instance, Universal Mobile Telecommunications System (UMTS) and High Speed Packet Access (HSPA)), and fourth generation (4G) technology (for instance, Long Term Evolution (LTE) and LTE-Advanced).

The technical specifications controlled by 3GPP can be expanded and revised by specification releases, which can span multiple years and specify a breadth of new features and evolutions.

In one example, 3GPP introduced carrier aggregation (CA) for LTE in Release 10. Although initially introduced with two downlink carriers, 3GPP expanded carrier aggregation in Release 14 to include up to five downlink carriers and up to three uplink carriers. Other examples of new features and evolutions provided by 3GPP releases include, but are not limited to, License Assisted Access (LAA), enhanced LAA (eLAA), Narrowband Internet of things (NB-IoT), Vehicle-to-Everything (V2X), and High Power User Equipment (HPUE).

3GPP introduced Phase 1 of fifth generation (5G) technology in Release 15, and introduced Phase 2 of 5G technology in Release 16. Subsequent 3GPP releases will further evolve and expand 5G technology. 5G technology is also referred to herein as 5G New Radio (NR).

5G NR supports or plans to support a variety of features, such as communications over millimeter wave spectrum, beamforming capability, high spectral efficiency waveforms, low latency communications, multiple radio numerology, and/or non-orthogonal multiple access (NOMA). Although such radio frequency (RF) functionalities offer flexibility to networks and enhance user data rates, supporting such features can pose a number of technical challenges.

The teachings herein are applicable to a wide variety of communication systems, including, but not limited to, communication systems using advanced cellular technologies, such as LTE-Advanced, LTE-Advanced Pro, and/or 5G NR.

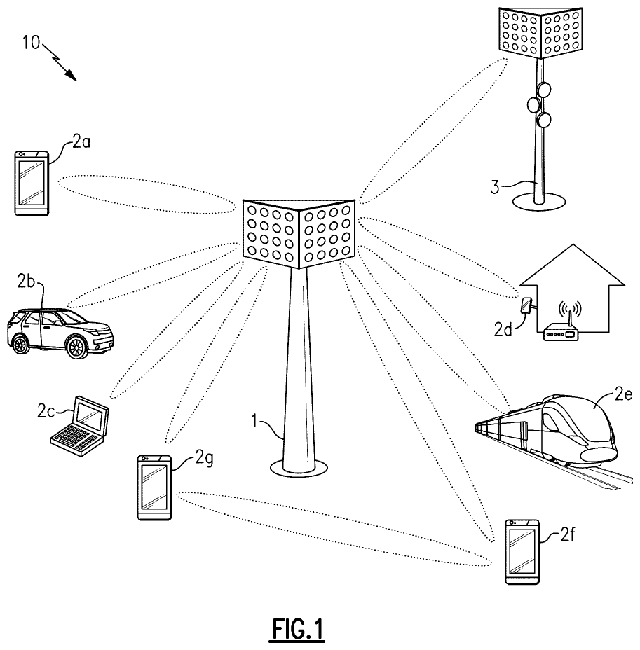

FIG. 1 is a schematic diagram of one example of a communication network 10. The communication network 10 includes a macro cell base station 1, a small cell base station 3, and various examples of user equipment (UE), including a first mobile device 2a, a wireless-connected car 2b, a laptop 2c, a stationary wireless device 2d, a wireless-connected train 2e, a second mobile device 2f, and a third mobile device 2g.

Although specific examples of base stations and user equipment are illustrated in FIG. 1, a communication network can include base stations and user equipment of a wide variety of types and/or numbers.

For instance, in the example shown, the communication network 10 includes the macro cell base station 1 and the small cell base station 3. The small cell base station 3 can operate with relatively lower power, shorter range, and/or with fewer concurrent users relative to the macro cell base station 1. The small cell base station 3 can also be referred to as a femtocell, a picocell, or a microcell. Although the communication network 10 is illustrated as including two base stations, the communication network 10 can be implemented to include more or fewer base stations and/or base stations of other types.

Although various examples of user equipment are shown, the teachings herein are applicable to a wide variety of user equipment, including, but not limited to, mobile phones, tablets, laptops, IoT devices, wearable electronics, customer premises equipment (CPE), wireless-connected vehicles, wireless relays, and/or a wide variety of other communication devices. Furthermore, user equipment includes not only currently available communication devices that operate in a cellular network, but also subsequently developed communication devices that will be readily implementable with the inventive systems, processes, methods, and devices as described and claimed herein.

The illustrated communication network 10 of FIG. 1 supports communications using a variety of cellular technologies, including, for example, 4G LTE and 5G NR. In certain implementations, the communication network 10 is further adapted to provide a wireless local area network (WLAN), such as WiFi. Although various examples of communication technologies have been provided, the communication network 10 can be adapted to support a wide variety of communication technologies.

Various communication links of the communication network 10 have been depicted in FIG. 1. The communication links can be duplexed in a wide variety of ways, including, for example, using frequency-division duplexing (FDD) and/or time-division duplexing (TDD). FDD is a type of radio frequency communications that uses different frequencies for transmitting and receiving signals. FDD can provide a number of advantages, such as high data rates and low latency. In contrast, TDD is a type of radio frequency communications that uses about the same frequency for transmitting and receiving signals, and in which transmit and receive communications are switched in time. TDD can provide a number of advantages, such as efficient use of spectrum and variable allocation of throughput between transmit and receive directions.

In certain implementations, user equipment can communicate with a base station using one or more of 4G LTE, 5G NR, and WiFi technologies. In certain implementations, enhanced license assisted access (eLAA) is used to aggregate one or more licensed frequency carriers (for instance, licensed 4G LTE and/or 5G NR frequencies), with one or more unlicensed carriers (for instance, unlicensed WiFi frequencies).

As shown in FIG. 1, the communication links include not only communication links between UE and base stations, but also UE to UE communications and base station to base station communications. For example, the communication network 10 can be implemented to support self-fronthaul and/or self-backhaul (for instance, as between mobile device 2g and mobile device 2f).

The communication links can operate over a wide variety of frequencies. In certain implementations, communications are supported using 5G NR technology over one or more frequency bands that are less than 6 Gigahertz (GHz) and/or over one or more frequency bands that are greater than 6 GHz. For example, the communication links can serve Frequency Range 1 (FR1) in the range of about 410 MHz to about 7.125 GHZ, Frequency Range 2 (FR2) in the range of about 24.250 GHz to about 52.600 GHz, or a combination thereof. In one embodiment, one or more of the mobile devices support a HPUE power class specification.

In certain implementations, a base station and/or user equipment communicates using beamforming. For example, beamforming can be used to focus signal strength to overcome path losses, such as high loss associated with communicating over high signal frequencies. In certain embodiments, user equipment, such as one or more mobile phones, communicate using beamforming on millimeter wave frequency bands in the range of 30 GHz to 300 GHz and/or upper centimeter wave frequencies in the range of 6 GHz to 30 GHz, or more particularly, 24 GHz to 30 GHz.

Different users of the communication network 10 can share available network resources, such as available frequency spectrum, in a wide variety of ways.

In one example, frequency division multiple access (FDMA) is used to divide a frequency band into multiple frequency carriers. Additionally, one or more carriers are allocated to a particular user. Examples of FDMA include, but are not limited to, single carrier FDMA (SC-FDMA) and orthogonal FDMA (OFDMA). OFDMA is a multicarrier technology that subdivides the available bandwidth into multiple mutually orthogonal narrowband subcarriers, which can be separately assigned to different users.

Other examples of shared access include, but are not limited to, time division multiple access (TDMA) in which a user is allocated particular time slots for using a frequency resource, code division multiple access (CDMA) in which a frequency resource is shared amongst different users by assigning each user a unique code, space-divisional multiple access (SDMA) in which beamforming is used to provide shared access by spatial division, and non-orthogonal multiple access (NOMA) in which the power domain is used for multiple access. For example, NOMA can be used to serve multiple users at the same frequency, time, and/or code, but with different power levels.

Enhanced mobile broadband (eMBB) refers to technology for growing system capacity of LTE networks. For example, eMBB can refer to communications with a peak data rate of at least 10 Gbps and a minimum of 100 Mbps for each user. Ultra-reliable low latency communications (uRLLC) refers to technology for communication with very low latency, for instance, less than 2 milliseconds. uRLLC can be used for mission-critical communications such as for autonomous driving and/or remote surgery applications. Massive machine-type communications (mMTC) refers to low cost and low data rate communications associated with wireless connections to everyday objects, such as those associated with Internet of Things (IoT) applications.

The communication network 10 of FIG. 1 can be used to support a wide variety of advanced communication features, including, but not limited to, eMBB, uRLLC, and/or mMTC.

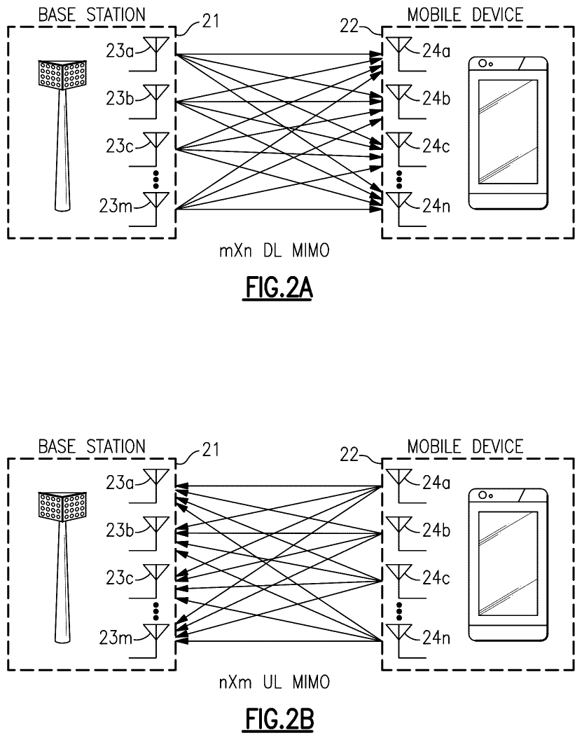

FIG. 2A is a schematic diagram of one example of a downlink channel using multi-input and multi-output (MIMO) communications. FIG. 2B is schematic diagram of one example of an uplink channel using MIMO communications.

MIMO communications use multiple antennas for simultaneously communicating multiple data streams over common frequency spectrum. In certain implementations, the data streams operate with different reference signals to enhance data reception at the receiver. MIMO communications benefit from higher SNR, improved coding, and/or reduced signal interference due to spatial multiplexing differences of the radio environment.

MIMO order refers to a number of separate data streams sent or received. For instance, MIMO order for downlink communications can be described by a number of transmit antennas of a base station and a number of receive antennas for UE, such as a mobile device. For example, two-by-two (2×2) DL MIMO refers to MIMO downlink communications using two base station antennas and two UE antennas. Additionally, four-by-four (4×4) DL MIMO refers to MIMO downlink communications using four base station antennas and four UE antennas.

In the example shown in FIG. 2A, downlink MIMO communications are provided by transmitting using M antennas 23a, 23b, 23c, . . . 23m of the base station 21 and receiving using N antennas 24a, 24b, 24c, . . . 24n of the mobile device 22. Accordingly, FIG. 2A illustrates an example of m×n DL MIMO.

Likewise, MIMO order for uplink communications can be described by a number of transmit antennas of UE, such as a mobile device, and a number of receive antennas of a base station. For example, 2×2 UL MIMO refers to MIMO uplink communications using two UE antennas and two base station antennas. Additionally, 4×4 UL MIMO refers to MIMO uplink communications using four UE antennas and four base station antennas.

In the example shown in FIG. 2B, uplink MIMO communications are provided by transmitting using N antennas 24a, 24b, 24c, . . . 24n of the mobile device 22 and receiving using M antennas 23a, 23b, 23c, . . . 23m of the base station 21. Accordingly, FIG. 2B illustrates an example of n×m UL MIMO.

By increasing the level or order of MIMO, bandwidth of an uplink channel and/or a downlink channel can be increased.

MIMO communications are applicable to communication links of a variety of types, such as FDD communication links and TDD communication links.

FIG. 3 is a schematic diagram of one embodiment of a mobile device 300.

The mobile device 300 includes a baseband system 301, a transceiver 302, a front end system 303, antennas 304, a power management system 305, a memory 306, a user interface 307, and a battery 308.

The mobile device 300 can be used communicate using a wide variety of communications technologies, including, but not limited to, 2G, 3G, 4G (including LTE, LTE-Advanced, and LTE-Advanced Pro), 5G NR, WLAN (for instance, WiFi), WPAN (for instance, Bluetooth and ZigBee), WMAN (for instance, WiMax), and/or GPS technologies.

The transceiver 302 generates RF signals for transmission and processes incoming RF signals received from the antennas 304. It will be understood that various functionalities associated with the transmission and receiving of RF signals can be achieved by one or more components that are collectively represented in FIG. 3 as the transceiver 302. In one example, separate components (for instance, separate circuits or dies) can be provided for handling certain types of RF signals.

The front end system 303 aids in conditioning signals transmitted to and/or received from the antennas 304. In the illustrated embodiment, the front end system 303 includes antenna tuning circuitry 310, power amplifiers (PAS) 311, low noise amplifiers (LNAs) 312, filters 313, switches 314, and signal splitting/combining circuitry 315. However, other implementations are possible.

For example, the front end system 303 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain implementations, the mobile device 300 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 304 can include antennas used for a wide variety of types of communications. For example, the antennas 304 can include antennas for transmitting and/or receiving signals associated with a wide variety of frequencies and communications standards.

In certain implementations, the antennas 4 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 300 can operate with beamforming in certain implementations. For example, the front end system 303 can include amplifiers having controllable gain and phase shifters having controllable phase to provide beam formation and directivity for transmission and/or reception of signals using the antennas 304. For example, in the context of signal transmission, the amplitude and phases of the transmit signals provided to the antennas 304 are controlled such that radiated signals from the antennas 304 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 304 from a particular direction. In certain implementations, the antennas 304 include one or more arrays of antenna elements to enhance beamforming.

The baseband system 301 is coupled to the user interface 307 to facilitate processing of various user input and output (I/O), such as voice and data. The baseband system 301 provides the transceiver 302 with digital representations of transmit signals, which the transceiver 302 processes to generate RF signals for transmission. The baseband system 301 also processes digital representations of received signals provided by the transceiver 302. As shown in FIG. 3, the baseband system 301 is coupled to the memory 306 of facilitate operation of the mobile device 300.

The memory 306 can be used for a wide variety of purposes, such as storing data and/or instructions to facilitate the operation of the mobile device 300 and/or to provide storage of user information.

The power management system 305 provides a number of power management functions of the mobile device 300. In certain implementations, the power management system 305 includes a PA supply control circuit that controls the supply voltages of the power amplifiers 311. For example, the power management system 305 can be configured to change the supply voltage(s) provided to one or more of the power amplifiers 311 to improve efficiency, such as power added efficiency (PAE).

As shown in FIG. 3, the power management system 305 receives a battery voltage from the battery 308. The battery 308 can be any suitable battery for use in the mobile device 300, including, for example, a lithium-ion battery.

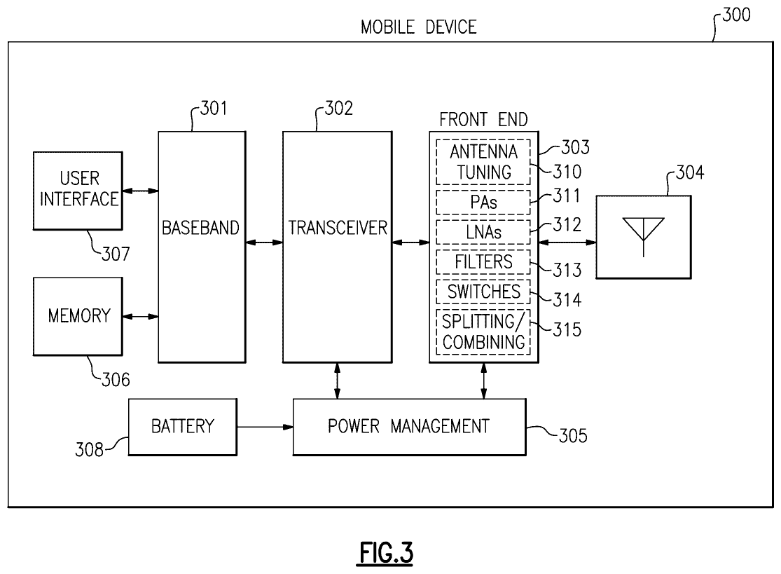

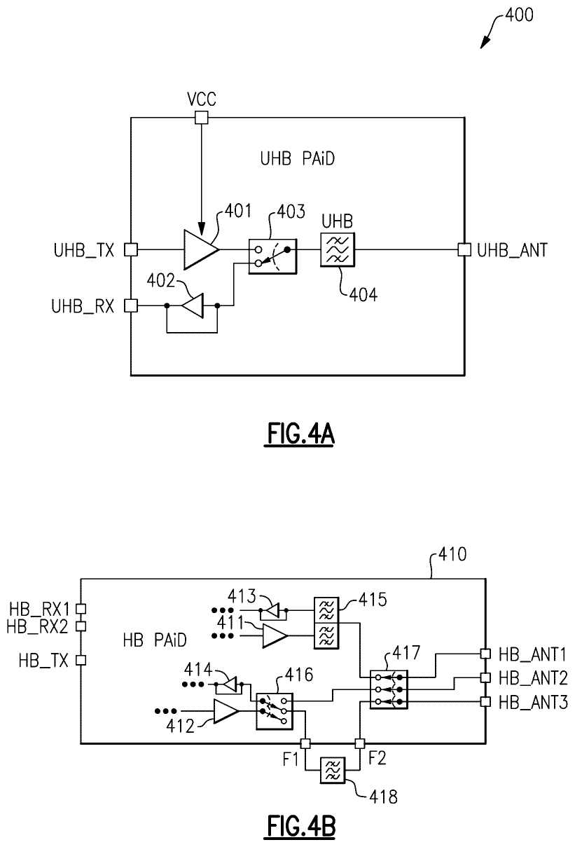

FIG. 4A is a schematic diagram of a UHB transmit and receive module 400 (i.e., a front-end module) according to one example. The UHB transmit and receive module 400 operates to generate a UHB signal for transmission and to process a UHB signal received from an antenna.

The UHB transmit and receive module 400 illustrates one implementation of a UHB module suitable for incorporation in a RF system, such as that of the mobile device 300 of FIG. 3. Although the UHB transmit and receive module 400 illustrates one implementation of a UHB module, the teachings herein are applicable to RF electronics including modules implemented in a wide variety of ways. For example, while the illustrated example is an ultra-high band (UHB) module, other embodiments can transmit and receive over bands having different (e.g., low-band, mid-band, or high-band) frequencies. Accordingly, other implementations of modules are possible, such as modules with more or fewer pins, different pins, more or fewer components, and/or a different arrangement of components.

The UHB transmit and receive module 400 includes a power amplifier 401, a low noise amplifier 402, a transmit/receive switch 403, and a UHB filter 404, which is used to pass one or more UHB bands, for instance, Band 42, Band 43, and/or Band 48. As will be discussed herein, the power amplifier 401 or the low noise amplifier 402 can include a bypass path connecting an input of the amplifier to an output of the amplifier without signal amplification. It will be understood by those skilled in the art that the bypass path(s) can be selectively coupled to either terminal of the amplifiers by a toggle switch or other mechanism. The bypass path(s) can further include signal conditioning and filtering stages and/or an impedance matching circuit. The UHB transmit and receive module 400 further includes pins, including a UHB_TX pin for receiving a UHB transmit signal for transmission, a UHB_RX pin for outputting a UHB receive signal, a UHB_ANT pin for connecting to an antenna, and a VCC pin for receiving a supply voltage for powering at least the power amplifier 401. In certain implementations, the VCC pin receives a shared supply voltage from a power management circuit (for example, a PMU, not shown) shared by multiple modules.

The illustrated UHB transmit and receive module 400 provides both transmit and receive functionality for UHB signals. Thus, when four instantiations of the UHB transmit and receive module 400 are coupled directly or indirectly to four antennas, both 4×4 RX MIMO for UHB and 4×4 TX MIMO for UHB can be achieved. Additionally, the UHB transmit and receive modules can be used to support carrier aggregation for UL and/or DL using one or more UHB carrier frequencies.

FIG. 4B is a schematic diagram of a high-band (HB) transmit and receive module 410 according to one example.

The RF systems disclosed herein can include one or more implementations of the HB transmit and receive module 410. Although the HB transmit and receive module 410 illustrates one implementation of an HB module, the teachings herein are applicable to RF electronics including HB modules implemented in a wide variety of ways as well as to RF electronics implemented without HB modules. For example, while the illustrated example is an HB module, other embodiments can transmit and receive over bands having different (e.g., low-band, mid-band, or ultra high-band) frequencies.

The HB transmit and receive module 410 includes a first power amplifier 411 for FDD communications, a second power amplifier 412 for TDD communications, a first low noise amplifier 413 for FDD communications, a second low noise amplifier 414 for TDD communications, an FDD duplexer 415, a transmit/receive switch 416, a multi-throw switch 417, and a pair of bypass paths corresponding to the first and second low noise amplifiers 413, 414. An external TDD filter 418 is also included in this example. In another example, the TDD filter 418 is included within the module 410.

The HB transmit and receive module 410 further includes a variety of pins, including an HB_TX pin for receiving an HB transmit signal for transmission, an HB_RX1 pin for outputting a first HB receive signal, an HB_RX2 pin for outputting a second HB receive signal, an F1 pin for connecting to one terminal of the external TDD filter 418, and an F2 pin for connecting to another terminal of the external TDD filter 418. The module 410 further includes an HB_ANT1 pin, an HB_ANT2 pin, and an HB_ANT3 pin for connecting to one or more antennas.

FIG. 4C is a schematic diagram of an exemplary MIMO front-end module 440 supporting uplink carrier aggregation.

The MIMO module 400 can include one or more instantiations of a power amplifier module (PAM) as discussed herein. The MIMO module 400 can include an MB RX switch 451, an HB RX switch 452, a TX band switch 453, an MB/HB antenna switch 454, a plurality of RX amplifiers 441-445 (e.g., low-noise amplifiers), power amplifier circuitry 456, a plurality of HB RX filters 461-463, and one or more MB filters 464. The MIMO module 440 further includes a variety of pins, including an MB_TX pin for receiving an MB transmit signal for transmission, MB_RX1 and MB_RX2 pins for outputting received MB signals, and HB_RX1 and HB_RX2 for outputting received HB signals. The module 440 further includes an MB/HB_ANT pin for connecting to one or more antennas. While the illustrated example is an MB/HB module, other embodiments can transmit and receive over bands having different (e.g., low-band or ultra-high band) frequencies.

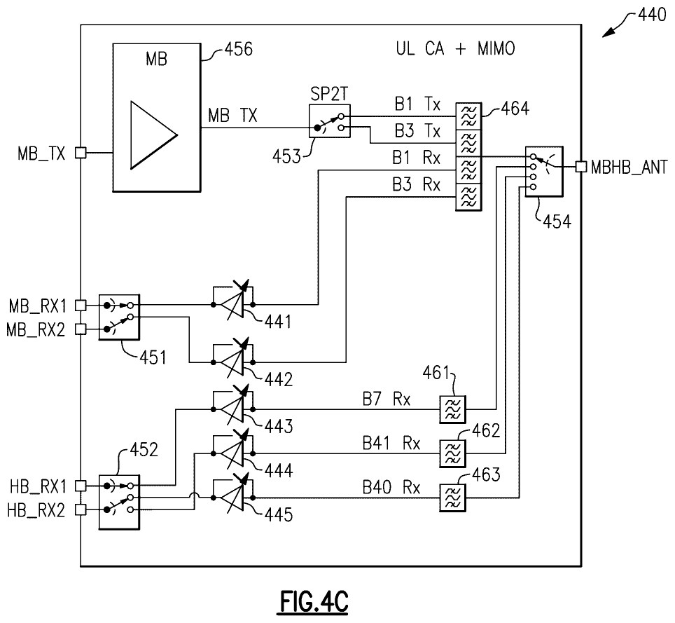

FIGS. 5A-5C are schematic diagrams of one embodiment of a power amplifier 500. The power amplifier 500 as illustrated is a low-noise amplifier (LNA) utilizing a cascode buffer architecture comprising a plurality of field-effect transistors (e.g., MOSFETs). The cascode buffer comprises a common-emitter input stage 501 feeding into a common-gate output stage 502, although those skilled in the art will envision alternate implementations. The input stage comprises a plurality of RF signal inputs (IN1, IN2, IN3, etc.) each connected to a gate of a corresponding input stage transistor 501a, 501b, or 501c. The signal inputs can each correspond to a different received signal band of a front-end module according to any of the previous figures, such as B1 RX, B3 RX, B7 RX, B41 RX, or B40 RX of the module 440 of FIG. 4C. The cascode buffer power amplifier 500 provides low input impedance, high gain, and low-noise amplification which is preferred for RF applications.

The power amplifier 500 includes a bypass path 510 to selectively couple each one of the plurality of signal inputs to an output (OUT) of the power amplifier 500 when no amplification is desired. FIG. 5B illustrates how a front-end module can enable the bypass path 510 for a first input (IN1) by closing a first switch 515 and a corresponding input switch when a received signal does not require amplification. The path of an RF signal along the bypass path 510 is generally shown by the dashed line 530. For each one of the plurality of signal inputs, the bypass path 510 includes a corresponding input switch to selectively couple an input signal to the output of the amplifier 500. The bypass path further includes a series capacitor 555 and a shunt inductor 560 which can be tuned for impedance matching of the output.

The path of the RF signal applied to IN1 through the power amplifier during gain/amplification operation is generally shown by the dashed line 540. As shown, the RF signal is amplified through the cascode buffer. The amplified output of the cascode buffer is selectively coupled via a switch 525 to the output (OUT) of the power amplifier 500. The amplified output of the cascode buffer is also connected to a notch filter 520 comprising an inductor coupled in series with a variable capacitor to ground. The notch filter 520 (also referred to as a band-stop filter) is configured to attenuate a specific frequency or a band of frequencies in the signal output of the power amplifier 500 corresponding to a resonant frequency of the inductor-capacitor (LC) circuit which forms the notch filter 520. The capacitance of the variable capacitor can be adjusted to tune the stop-band of the notch filter 520 to attenuate undesired frequencies in a front-end module. For example, the filter 520 can be configured to attenuate a TX frequency of the front-end module or an adjacent front-end module to eliminate crosstalk.

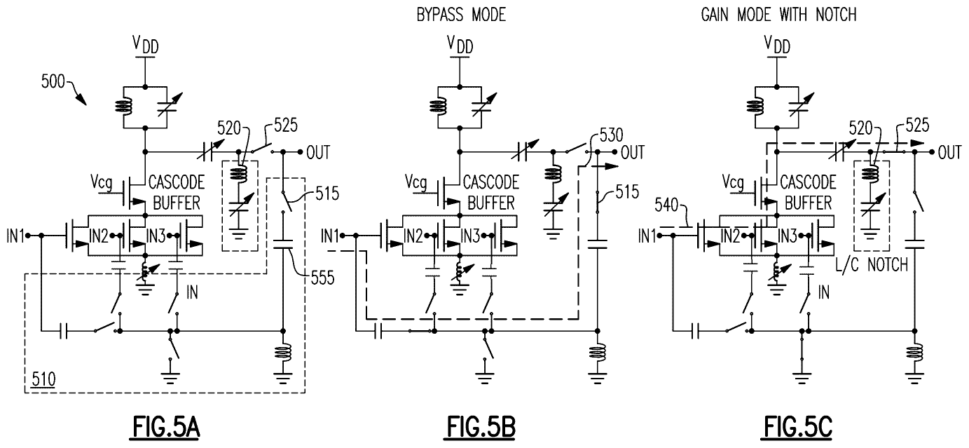

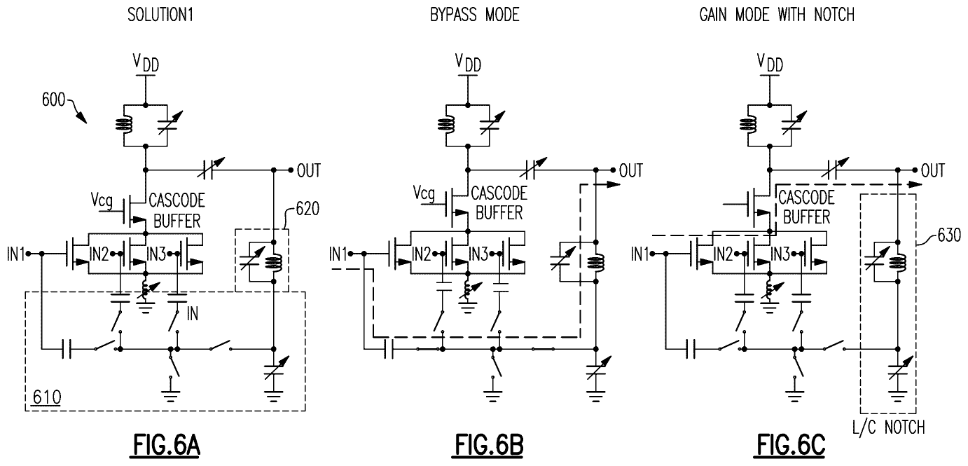

FIGS. 6A-6C are schematic diagrams of another embodiment of a power amplifier 600. Because the power amplifier 600 is often a component of a packaged module (such as the front-end modules of FIGS. 4A-4C), a power amplifier with fewer components is preferred to shrink the package size. This difference is particularly noticeable in modules having multiple power amplifiers, such as the plurality of LNAs 441-445 each corresponding to a different RX band of the module 440. Accordingly, reducing the number of components by combining duplicate components in the packaged module can reduce manufacturing costs and provide a smaller footprint overall.

The power amplifier 600 combines a bypass path 610 and a notch filter 630 as part of a unified circuit, such that the same functionality of the power amplifier 500 with bypass can be provided by a circuit with only a single inductor. Because inductors are usually the largest single components of a circuit, a module with relatively fewer inductors will generally have a smaller footprint than a module with fewer capacitors.

Instead of providing a single series capacitor in the bypass path 610, each one of the plurality of signal inputs of the power amplifier 600 can have an input capacitor connecting the signal input to the corresponding input switch. In some cases, the input capacitors can be variable capacitors to tune the output of the circuit as discussed herein.

The bypass path 610 further includes an LC component 620 comprising a variable capacitor 621 and an inductor 622 in parallel with the capacitor 621. The LC component 620 is connected to a variable shunt capacitor 611 to collectively form an LC notch filter 630. When a mode select switch 612 connecting one of the plurality of signal inputs IN1, IN2, IN3 to the LC component 620 is closed, the bypass path 610 operates similarly to the previous example, connecting the input RF signal to a non-amplified output of the power amplifier 600. When the mode select switch 612 connecting one of the plurality of signal inputs IN1, IN2, IN3 to the LC component 620 is open, the variable shunt capacitor 611 and the LC component 620 forming the LC notch filter 630 are disconnected from the bypass path 610, behaving as a notch filter for the amplified RF signal output.

Because the LC component 620 is used for both impedance matching of the signal output (bypass operation) and tuning the stop-band of the LC notch filter 630 (amplifier/gain operation), in most cases the same inductance values are not preferred for both operating modes. For relatively low values of the inductor 622, the resonant frequency of the LC notch filter 630 will generally be higher. The LC component 620 therefore further includes the parallel variable capacitor 621 for adaptively tuning the stop-band of the LC notch filter 630. As will be appreciated by those skilled in the art, the capacitance of the parallel variable capacitor 621 can be set to achieve a preferred resonant frequency for the LC notch filter 630 during signal amplification without compromising the bypass path impedance in the bypass mode. Advantageously, the parallel variable capacitor 621 can also be adjusted based on the frequency band of the input signal such that the LC notch filter 630 attenuates a different frequency or range of frequencies according to which one of the signal inputs to the amplifier 600 is currently active. This adjustment may occur automatically during signal amplification by the power amplifier 600 or be directed by control logic of the front-end module.

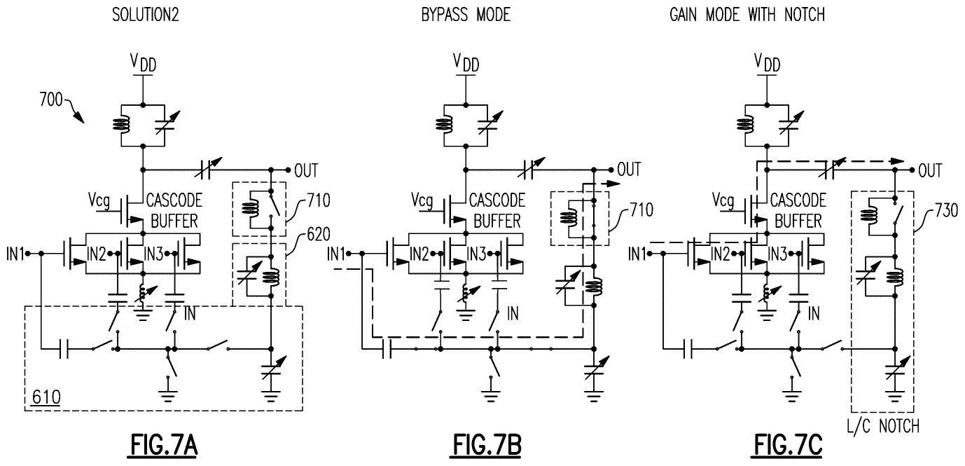

FIGS. 7A-7C are schematic diagrams of yet another embodiment of a power amplifier 700. The bypass path 610 of the power amplifier 700 is substantially the same as in the example of FIGS. 6A-6C, except for the addition of a parallel circuit 710 comprising a second series inductor and a parallel toggle switch. The second series inductor of the parallel circuit 710 can be selectively enabled by opening the toggle switch to further increase the inductance of an LC circuit comprising the LC component 620 and the variable shunt capacitor 611, allowing for a lower range of frequencies to be filtered by an LC notch filter 730. In certain embodiments, the inductor 622 and the inductor of the parallel circuit 710 may also be combined into single center-tapped inductor with the toggle switch configured to selectively connect the center tap to the bypass path 610.

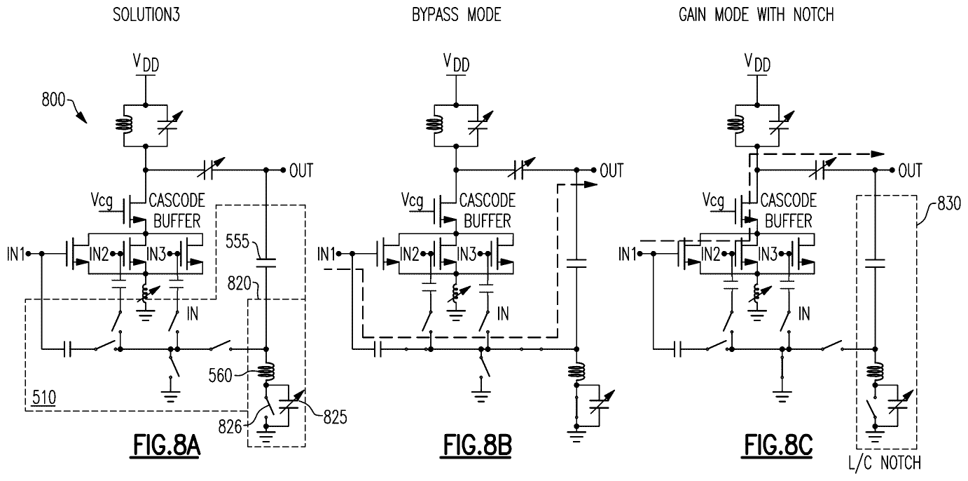

FIGS. 8A-8C are schematic diagrams of an additional embodiment of a power amplifier 800. A shunt circuit 820 comprising the shunt inductor 560, a variable shunt capacitor 825, and a toggle switch 826 connected in parallel with the capacitor 825 is configured to couple RF signals to a circuit ground. The parallel toggle switch 826 is provided to selectively bypass the variable shunt capacitor 825 and to short the shunt inductor 560 directly to the circuit ground. Accordingly, the series capacitor 555 and the shunt circuit 820 collectively form an LC notch filter 830, wherein the resonant frequency of the notch filter 830 can be tuned by enabling and selectively tuning the variable shunt capacitor 825. During gain operation of the amplifier 800, the parallel toggle switch 826 can be opened to increase the capacitance of the shunt circuit 820 and therefore further decrease the resonant frequency of the LC notch filter 830.

In some cases, the power amplifier 800 may be preferred over the power amplifier 700 of FIGS. 7A-7C because the amplifier 800 does not include additional inductors or a center-tapped inductor having a higher inductance. However, those skilled in the art will envision useful RF applications for the power amplifiers with bypass paths of any of the previous figures.

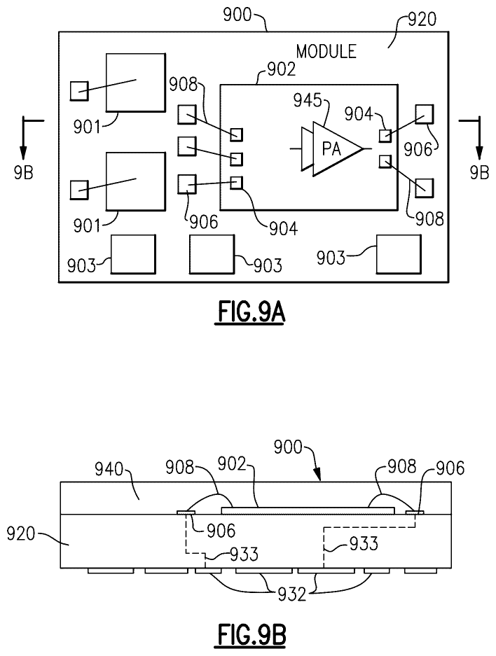

FIG. 9A is a schematic diagram of one embodiment of a packaged module 900, such as the front-end modules of FIGS. 4A-4C. FIG. 9B is a schematic diagram of a cross-section of the packaged module 900 of FIG. 9A taken along the lines 9B-9B.

The packaged module 900 includes radio frequency components 901, a semiconductor die 902, surface mount devices 903, wirebonds 908, a package substrate 920, and an encapsulation structure 940. The package substrate 920 includes pads 906 formed from conductors disposed therein. Additionally, the semiconductor die 902 includes pins or pads 904, and the wirebonds 908 have been used to connect the pads 904 of the die 902 to the pads 906 of the package substrate 920.

The semiconductor die 902 includes a power amplifier 945, which can be implemented in accordance with one or more features disclosed herein.

The packaging substrate 920 can be configured to receive a plurality of components such as radio frequency components 901, the semiconductor die 902 and the surface mount devices 903, which can include, for example, surface mount capacitors and/or inductors. In one implementation, the radio frequency components 901 include integrated passive devices (IPDs).

As shown in FIG. 9B, the packaged module 900 is shown to include a plurality of contact pads 932 disposed on the side of the packaged module 900 opposite the side used to mount the semiconductor die 902. Configuring the packaged module 900 in this manner can aid in connecting the packaged module 900 to a circuit board, such as a phone board of a mobile device. The example contact pads 932 can be configured to provide radio frequency signals, bias signals, and/or power (for example, a power supply voltage and ground) to the semiconductor die 902 and/or other components. As shown in FIG. 9B, the electrical connections between the contact pads 932 and the semiconductor die 902 can be facilitated by connections 933 through the package substrate 920. The connections 933 can represent electrical paths formed through the package substrate 920, such as connections associated with vias and conductors of a multilayer laminated package substrate.

In some embodiments, the packaged module 900 can also include one or more packaging structures to, for example, provide protection and/or facilitate handling. Such a packaging structure can include overmold or encapsulation structure 940 formed over the packaging substrate 920 and the components and die(s) disposed thereon.

It will be understood that although the packaged module 900 is described in the context of electrical connections based on wirebonds, one or more features of the present disclosure can also be implemented in other packaging configurations, including, for example, flip-chip configurations.

Aspects of this disclosure can be implemented in various electronic devices. Examples of the electronic devices can include, but are not limited to, consumer electronic products, parts of the consumer electronic products such as packaged radio frequency modules, radio frequency filter die, uplink wireless communication devices, wireless communication infrastructure, electronic test equipment, etc. Examples of the electronic devices can include, but are not limited to, a mobile phone such as a smart phone, a wearable computing device such as a smart watch or an ear piece or smart eyeglasses or virtual reality equipment, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, IoT radios, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly coupled, or coupled by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, filters, multiplexer, devices, modules, wireless communication devices, apparatus, methods, and systems described herein may be embodied in a variety of other forms. Furthermore, various omissions, substitutions and changes in the form of the resonators, filters, multiplexer, devices, modules, wireless communication devices, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. A radio frequency amplifier comprising:
an output, a plurality of transistors arranged to form an amplification path coupled to the output, and a bypass path coupled to the output;
an LC component including a first capacitor and an inductor connected to an output of the amplifier; and
a switch to selectively connect an input of the radio frequency amplifier to the bypass path during a bypass mode of operation and to disconnect the input of the radio frequency amplifier from the bypass path in a gain mode of operation, the LC component connected to the amplification path in the gain mode of operation and connected to the bypass path in the bypass mode of operation.

2. The radio frequency amplifier of claim 1 wherein the LC component provides impedance matching at the output in the bypass mode of operation.

3. The radio frequency amplifier of claim 1 wherein the bypass path is to connect the input of the amplifier to the output of the amplifier without signal amplification.

4. The radio frequency amplifier of claim 3 wherein the amplifier includes no more than a single inductor.

5. The radio frequency amplifier of claim 3 further including a second capacitor connected in parallel with the inductor.

6. The radio frequency amplifier of claim 5 wherein the LC component and the second capacitor form a notch filter tuned to attenuate a range of frequencies at the output in the gain mode of operation.

7. The radio frequency amplifier of claim 6 wherein the first capacitor or the second capacitor is a variable capacitor.

8. The radio frequency amplifier of claim 1 wherein the amplification path is a cascode buffer including two or more field-effect transistors which form an input stage and an output stage.

9. The radio frequency amplifier of claim 8 wherein each one of the plurality of inputs is connected to the bypass path by a corresponding capacitor.

10. The radio frequency amplifier of claim 1 wherein the amplifier is a low-noise amplifier.

11. A radio frequency front-end module comprising:
an antenna switch module;
a transmit path; and
a receive path including an amplifier and a receive filter, the amplifier including an output, a plurality of transistors arranged to form an amplification path coupled to the output, a bypass path coupled to the output, an LC component including a first capacitor and an inductor connected to an output of the amplifier; and a switch to selectively connect an input of the amplifier to the bypass path during a bypass mode of operation and to disconnect the input of the amplifier from the bypass path in a gain mode of operation, the LC component connected to the amplification path in the gain mode of operation and connected to the bypass path in the bypass mode of operation.

12. The radio frequency front-end module of claim 11 wherein the amplifier is a low noise amplifier and the LC component provides impedance matching at the output in the bypass mode of operation.

13. The radio frequency front-end module of claim 11 wherein the bypass path is to connect the input of the amplifier to the output without signal amplification.

14. The radio frequency front-end module of claim 13 further including a second capacitor connected in parallel with the inductor.

15. The radio frequency front-end module of claim 14 wherein the LC component and the second capacitor form a notch filter tuned to attenuate a range of frequencies at the output of the amplifier in the gain mode of operation.

16. The radio frequency front-end module of claim 15 wherein the first capacitor or the second capacitor is a variable capacitor.

17. The radio frequency front-end module of claim 11 wherein the amplification path is a cascode buffer including two or more field-effect transistors which form an input stage and an output stage.

18. The radio frequency front-end module of claim 11 wherein each one of the plurality of inputs is connected to the bypass path by a corresponding capacitor.

19. A mobile device comprising:
a transceiver;
a front-end module communicatively connected to the transceiver, the front-end module including an antenna switch module, a transmit path, and a receive path including an amplifier and a receive filter, the amplifier including an output, a plurality of transistors arranged to form an amplification path coupled to the output, a bypass path coupled to the output, an LC component including a first capacitor and an inductor connected to an output of the amplifier; and a switch to selectively connect an input of the amplifier to the bypass path during a bypass mode operation and to disconnect the input of the radio frequency amplifier from the bypass path in a gain mode of operation, the LC component connected to the amplification path in the gain mode of operation and connected to the bypass path in the bypass mode of operation; and
an antenna communicatively connected to the front-end module.
